(19) United States
(12) Patent Application Publication
(10) Pub. No.: US 2013/0286585 A1
(43) Pub. Date: Oct. 31, 2013

(54) HEAT DISSIPATING MODULE, AND ELECTRONIC DEVICE AND OPERATING METHOD USING SAME

(71) Applicant: HON HAI PRECISION INDUSTRY CO., LTD., New Taipei (TW)

(72) Inventor: YAO-TING CHANG, New Taipei (TW)

(73) Assignee: HON HAI PRECISION INDUSTRY CO., LTD., New Taipei (TW)

(21) Appl. No.: 13/859,549

(22) Filed: Apr. 9, 2013

(30) Foreign Application Priority Data
Apr. 27, 2012 (TW) 101115240

(51) Int. Cl. H05K 7/20

(52) U.S. Cl. CPC H05K 7/20154; H05K 7/2039
USPC 361/695; 361/720

(57) ABSTRACT

A heat dissipating module is mounted on a mainboard of an electronic device. The heat dissipating module includes a guiding cover mounted on the mainboard, and a heat dissipater mounted on the mainboard and received in the guiding cover. A guiding cover switch is electrically connected to the mainboard and the guiding cover, and a heat dissipater switch is electrically connected to the mainboard and the heat dissipater. The connection states of the guiding cover switch and heat dissipater switch are both required to be on, proving that the guiding cover and the heat dissipater are both mounted properly on the mainboard, before allowing startup of the electronic device.

### BACKGROUND

1. Technical field

The disclosure generally relates to heat dissipating modules, and particularly to a heat dissipating module for mainboard of an electronic device.

2. Description of the Related Art

A mainboard of an electronic device (e.g., a personal computer) generates substantial heat while operating. Usually, a heat dissipating module is mounted on the mainboard to dissipate heat from the mainboard. However, in some systems, prior to use, there is no easy way to determine whether the heat dissipating module is mounted properly. When the heat dissipating module is not properly mounted to the mainboard when assembling or maintaining the electronic device, the mainboard working without the heat dissipating module may be damaged by the heat it generates.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present embodiments.

FIG. 1 is an isometric view of an electronic device having a heat dissipating module, according to an exemplary embodiment.

FIG. 2 is an exploded view of the heat dissipating module of FIG. 1.

FIG. 3 is a partially assembled, isometric view of the heat dissipating module of FIG. 1.

FIG. 4 is a flow-chart of an operating method of the heat dissipating module of FIG. 1.

### DETAILED DESCRIPTION

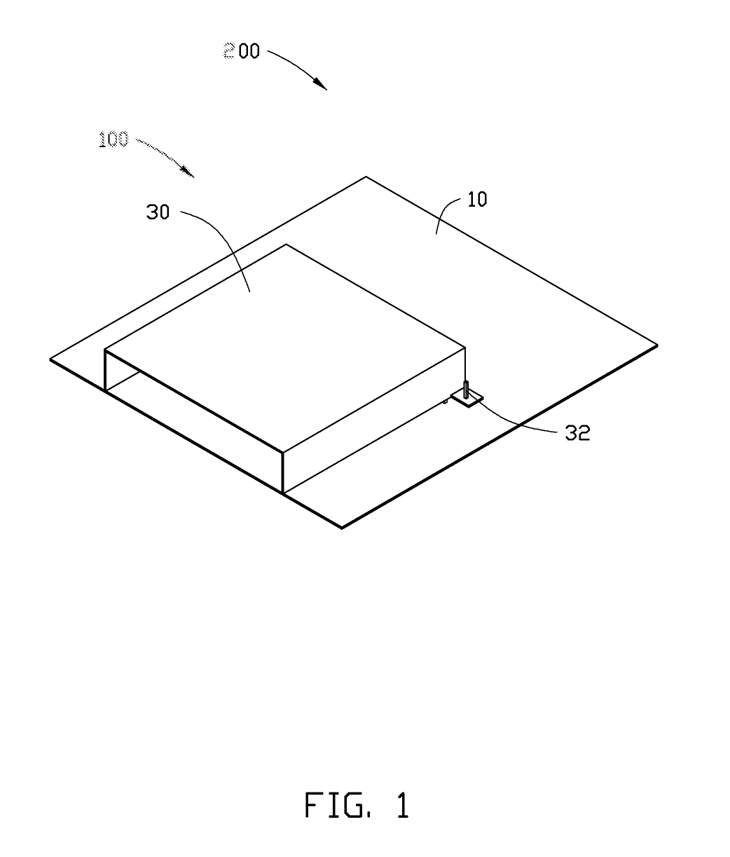

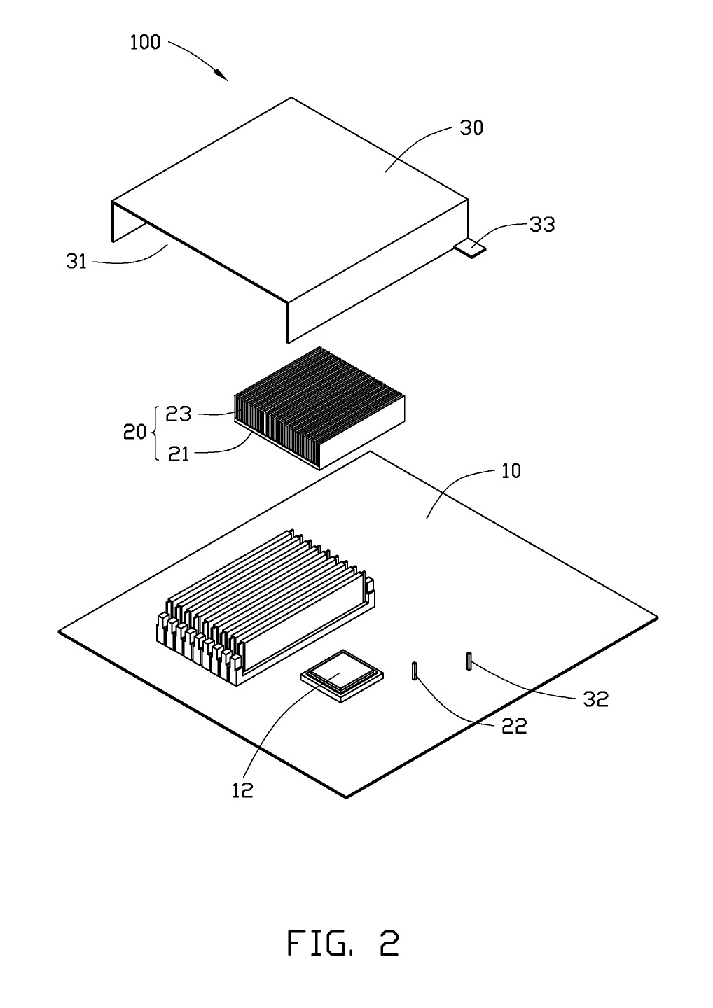

FIG. 1 shows an electronic device 200 having a heat dissipating module 100, according to an exemplary embodiment. The electronic device 200 may be, for example, a personal computer which includes a mainboard 10. The heat dissipating module 100 is mounted on the mainboard 10 and dissipates heat from the mainboard 10. FIG. 2 shows an exploded view of the heat dissipating module 100 of FIG. 1. The heat dissipating module 100 includes a heat dissipater 20, a heat dissipater switch 22, a guiding cover 30, and a guiding cover switch 32. The heat dissipater 20 and the guiding cover 30 are both mounted on the mainboard 10, the heat dissipater 20 is received inside the guiding cover 30. The heat dissipater 20 conducts heat away from the mainboard 10. The heat dissipating module 100 further includes one or more conventional fans (not shown), a fan generates airflow towards the heat dissipater 20 and the guiding cover 30, so that airflow collects and dissipates heat from the heat dissipater 20 and the guiding cover 30.

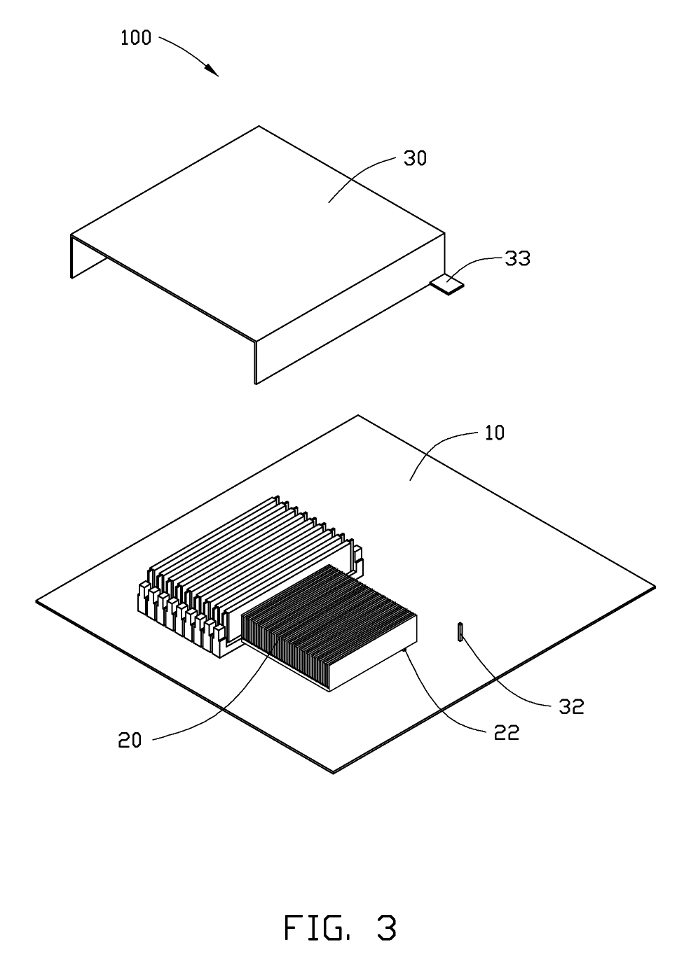

FIG. 3 is a partially assembled, isometric view of the heat dissipating module 100 of FIG. 1. At least one chip 12 is mounted on the mainboard 10, for example, a central processing unit (CPU). The chip 12 generates heat while operating. The heat dissipater 20 is mounted on the chip 12. The heat dissipater 20 includes a base 21 and a plurality of fins 23, which can be made by stamping process. The fins 23 are perpendicular to the base 21. The base 21 clings to the chip 12, the base 21 is made of heat conducting material which conducts heat from the chip 12 to the fins 23. One end of the heat dissipater 20 defines a vertical connecting hole (not shown). The heat dissipater switch 22 is inserted into the connecting hole, and connected to the mainboard 10 and the heat dissipater 20, and detects when the heat dissipater 20 is properly mounted on the mainboard 10. When the heat dissipater 20 is mounted at a predetermined position on the mainboard 10, one end of the heat dissipater switch 22 is electrically connected to the mainboard 10, while the other end is electrically connected to the heat dissipater 20, and the heat dissipater switch is closed in this situation; otherwise the heat dissipater switch 22 cuts off. When the heat dissipater switch 22 cuts off, the computer system of the electronic device 200 cannot be started, which avoids the situation of the computer system starting up and running without a functioning heat dissipater 20.

The guiding cover 30 is the shape of an upside-down U and has two opposite openings 31. The guiding cover 30 covers the heat dissipater 20. The fan or fans are mounted at one end of the guiding cover 30 and are aligned with one of the openings 31. The airflow generated by the fans passes from one opening 31 to the other opening 31, taking any heat from below the guiding cover 30, thus lowering the temperature of the chip 12.

The guiding cover 30 includes a connecting portion 33 formed on one end thereof. The guiding cover switch 32 is inserted through the connecting portion 33 and is connected to the mainboard 10 and the guiding cover 30. The guiding cover switch 32 is activated (that is, turns on) when the guiding cover 30 is properly mounted on the mainboard 10. When the guiding cover 30 is mounted at a predetermined position on the mainboard 10, one end of the guiding cover switch 32 is electrically connected to the mainboard 10, while the other end is electrically connected to the guiding cover 30, and the guiding cover switch 32 is closed in this situation; otherwise the guiding cover switch 32 cuts off. When the guiding cover switch 32 cuts off, the computer system cannot be started, which avoids the situation of the computer system starting up without the guiding cover 30 being properly mounted.

In the present embodiment, the personal computer further includes a chassis switch (not shown), thus when the chassis is closed (that is, fully assembled), the chassis switch is closed, and the fans mounted inside the chassis can work as designed. When the chassis switch is cut off, the computer system controls the fans to work at a higher speed to ensure additional heat dissipation from the chassis.

In the present embodiment, the connecting state of the heat dissipater switch 22 and of the guiding cover switch 32 are included in a startup item of the computer system, such as the POST procedure. When the computer system starts up, the computer system detects the connecting state of the heat dissipater switch 22 and of the guiding cover switch 32, and when the heat dissipater switch 22 and the guiding cover switch 32 are both closed, the computer system does start up; otherwise the computer system does not proceed to start up, and a warning is displayed on a monitor of the computer regarding the heat dissipater 20 and the guiding cover 30.

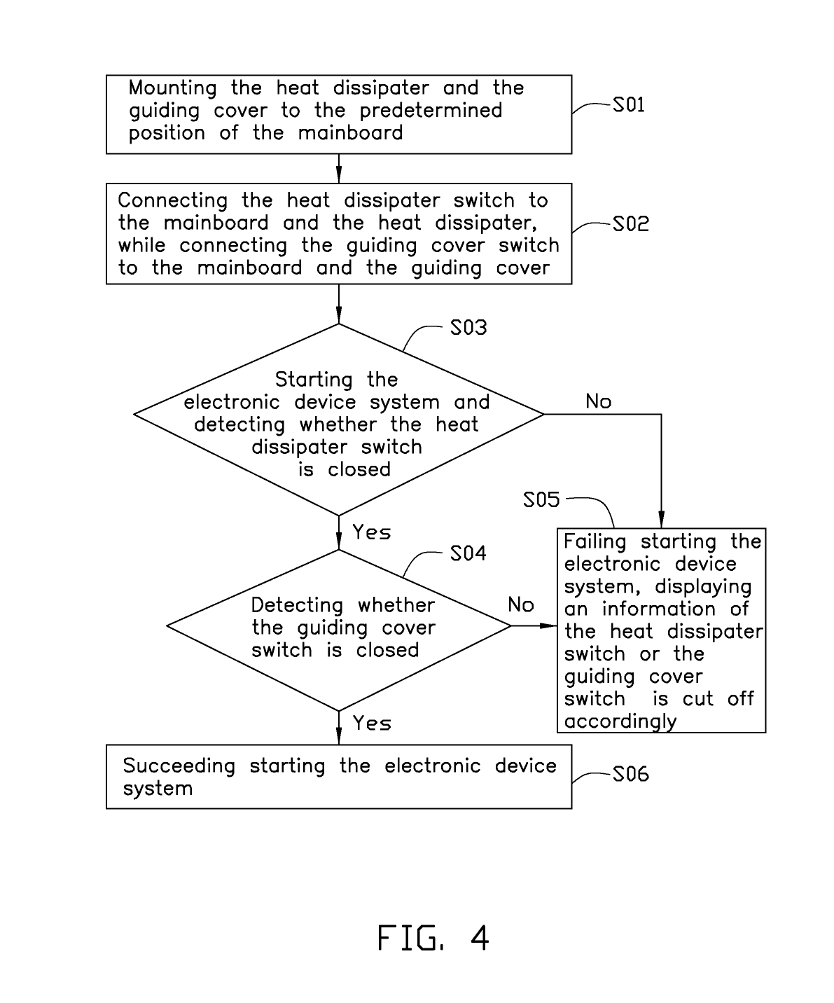

FIG. 4. is a flow chart of an operating method of the heat dissipating module 100 of the electronic device 200 of FIG. 1, the operating method of the heat dissipating module 100 includes the following steps:

Step 01, mounting the heat dissipater 20 and the guiding cover 30 to the correct and predetermined positions of the mainboard 10.

Step 02, connecting the heat dissipater switch 22 to the mainboard 10 and the heat dissipater 20, while connecting the guiding cover switch 32 to the mainboard 10 and the guiding cover 30.

Step 03, starting electronic device system of the electronic device and detecting whether the heat dissipater switch 22 is closed. In the present embodiment, the electronic device system can be a computer system, and when the heat dissipater switch 22 is closed, step 04 is invoked; otherwise step 05 is applied. In the present step 03, the heat dissipater switch 22 is closed when the heat dissipater 20 is mounted to the predetermined position of the mainboard 10.

Step 04, detecting whether the guiding cover switch 32 is closed. When the guiding cover switch 32 is closed, step 06 is invoked; otherwise step 05 is followed. In the present step 04, the guiding cover switch 32 is closed when the guiding cover 30 is mounted to the predetermined position of the mainboard 10.

Step 05, preventing a start up of the electronic device system, and displaying information regarding the heat dissipater switch 22 and the guiding cover switch 32. The monitor of the electronic device displays the information.

Step 06, successfully starting the electronic device system to bring about normal running.

Steps 03 and 04 can be exchanged, the detection of the connecting state of the heat dissipater switch 22 and of the guiding cover switch 32 can be in any order.

Thus, the heat dissipating module 100 mounts the heat dissipater switch 22 between the mainboard 10 and the heat dissipater 20, and mounts the guiding cover switch 32 between the mainboard 10 and the guiding cover 30, to ensure that the heat dissipater 20 and the guiding cover 30 are both mounted to predetermined positions of the mainboard 10, avoiding the electronic device system starting up without a heat dissipating module 100 which is working properly. Thus, the electronic device 200 using the heat dissipating module 100 has more protection and is safer.

Although numerous characteristics and advantages of the exemplary embodiments have been set forth in the foregoing description, together with details of the structures and functions of the exemplary embodiments, the disclosure is illustrative only, and changes may be made in detail, especially in the matters of arrangement of parts within the principles of disclosure to the full extent indicated by the broad general meaning of the terms in which the appended claims are expressed.

What is claimed is:

1. A heat dissipating module mounted on a mainboard of an electronic device, the heat dissipating module comprising:
a guiding cover mounted on the mainboard;
a heat dissipater mounted on the mainboard and received inside the guiding cover;
a guiding cover switch electrically connected to the mainboard and the guiding cover; and
a heat dissipater switch electrically connected to the mainboard and the heat dissipater;
wherein connection states of the guiding cover switch and the heat dissipater switch are required to be on, proving that the guiding cover and the heat dissipater are both mounted properly on the mainboard, before allowing startup of the electronic device.

2. The heat dissipating module as claimed in claim 1, wherein when the heat dissipater is mounted at a predetermined position of the mainboard, one end of the heat dissipater switch is electrically connected to the mainboard, while the other end is electrically connected to the heat dissipater, and the heat dissipater switch is closed; otherwise the heat dissipater switch cuts off.

3. The heat dissipating module as claimed in claim 2, wherein when the guiding cover is mounted at a predetermined position of the mainboard, one end of the guiding cover switch is electrically connected to the mainboard, while the other end is electrically connected to the guiding cover, and the guiding cover switch is closed; otherwise the guiding cover switch is cut off.

4. The heat dissipating module as claimed in claim 3, wherein when the heat dissipater switch or the guiding cover switch cuts off, the electronic device system cannot be started up.

5. The heat dissipating module as claimed in claim 4, wherein the heat dissipater switch is inserted into the heat dissipater.

6. The heat dissipating module as claimed in claim 5, wherein the guiding cover includes a connecting portion on one end, and the guiding cover switch is inserted through the connecting portion.

7. The heat dissipating module as claimed in claim 1, wherein the guiding cover is in shape of an upside-down U and has two opposite openings, the guiding cover covers the heat dissipater.

8. The heat dissipating module as claimed in claim 7, wherein one of the opening is aligned with the fans mounted adjoined to one end of the guiding cover.

9. An operating method of a heat dissipating module for an electronic device comprising:
mounting a heat dissipater and a guiding cover at predetermined positions of a mainboard of the electronic device;
mounting a heat dissipater switch between the mainboard and the heat dissipater and a guiding cover switch between the mainboard and the guiding cover;
starting electronic device system and detecting whether the heat dissipater switch is closed, when the heat dissipater switch is closed, the next step will be invoked; otherwise, preventing a start up of the electronic device system and displaying information regarding the heat dissipater;
detecting whether the guiding cover switch is closed, when the guiding cover switch is closed, the next step will be invoked; otherwise, preventing a start up of the electronic device system and displaying information regarding the guiding cover switch;
successfully starting the electronic device system.

10. The operating method as claimed in claim 9, wherein the heat dissipater switch and the guiding cover switch are closed when the heat dissipater and the guiding cover are mounted at the predetermined positions of the mainboard, one end of the heat dissipater switch is electrically connected to the mainboard, while the other end is electrically connected to the heat dissipater; and one end of the guiding cover switch is electrically connected to the mainboard, while the other end is electrically connected to the guiding cover.

11. The operating method as claimed in claim 10, wherein the steps of detection of the connecting states of the heat dissipating switch and of the guiding cover switch can be done in any order.

12. An electronic device comprising:
a mainboard;
a heat dissipating module mounted on the mainboard and comprising:
a guiding cover mounted on the mainboard;
a heat dissipater mounted on the mainboard and received in the guiding cover;
a guiding cover switch electrically connected to the mainboard and the guiding cover;
a heat dissipater switch electrically connected to the mainboard and the heat dissipater;
wherein connection states of the guiding cover switch and heat dissipater switch are both required to be on, proving that the guiding cover and the heat dissipater are both mounted properly on the mainboard, before allowing startup of the electronic device.

13. The electronic device as claimed in claim 12, wherein when the heat dissipater is mounted at a predetermined position of the mainboard, one end of the heat dissipater switch is electrically connected to the mainboard, while the other end is electrically connected to the heat dissipater, then the heat dissipater switch is closed; otherwise the heat dissipater switch cuts off.

14. The electronic device as claimed in claim 13, wherein when the guiding cover is mounted at a predetermined position of the mainboard, one end of the guiding cover switch is electrically connected to the mainboard, while the other end is electrically connected to the guiding cover, then the guiding cover switch is closed; otherwise the guiding cover switch cuts off.

15. The electronic device as claimed in claim 14, wherein when the heat dissipater switch or the guiding cover switch cuts off, the electronic device system cannot be started up.

16. The electronic device as claimed in claim 15, wherein the heat dissipater switch is inserted into the heat dissipater.

17. The electronic device as claimed in claim 16, wherein the guiding cover includes a connecting portion on one end, the guiding cover switch is inserted through the connecting portion.

18. The electronic device as claimed in claim 16, wherein the guiding cover is in a shape of an upside-down U and has two opposite openings, the guiding cover covers the heat dissipater.

19. The electronic device as claimed in claim 12, wherein one of the opening is aligned with the fans mounted adjoined to one end of the guiding cover.
